(19) United States
(12) Patent Application Publication
(10) Pub. No.: US 2023/0317758 A1
(43) Pub. Date: Oct. 5, 2023

(54) ISOLATION STRUCTURES IN IMAGE SENSORS

(71) Applicant: Taiwan Semiconductor Manufacturing Co., Ltd., Hsinchu (TW)

(72) Inventors: Cheng-Ying Ho, Chiayi Country 621 (TW); Kuan-Hua Lin, New Taipei City (TW); Keng-Yu Chou, Kaohsiung City 807 (TW); Kai-Chun Hsu, Yonghe City (TW); Sung-En Lin, Taoyuan City (TW); Wen-De Wang, Chiayi County 621 (TW); Jen-Cheng Liu, Hsin-Chu City (TW)

(73) Assignee: Taiwan Semiconductor Manufacturing Co., Ltd., Hsinchu (TW)

(21) Appl. No.: 17/879,556

(22) Filed: Aug. 2, 2022

Related U.S. Application Data
(60) Provisional application No. 63/327,018, filed on Apr. 4, 2022.

(51) Int. Cl. H01L 27/146

(52) U.S. Cl. CPC H01L 27/1463; H01L 27/14645; H01L 27/14621; H01L 27/14623; H01L 27/14625; H01L 27/14627; H01L 27/1464; H01L 27/14685

(57) ABSTRACT

An optical device with isolation structures and a method of fabricating the same are disclosed. The optical device includes a substrate having a first surface and a second surface opposite to the first surface, first and second radiation sensing devices disposed in the substrate, a first isolation structure disposed in the substrate. The first isolation structure has a first surface and a second surface opposite to the first surface. The optical device further includes a second isolation structure disposed in the substrate and on the first surface of the first isolation structure. The second isolation structure includes a metal structure and a dielectric layer surrounding the metal structure. The second isolation structure vertically extends over the first surface of the substrate.

### CROSS-REFERENCE TO RELATED APPLICATION

This application claims the benefit of U.S. Provisional Patent Application No. 63/327,018, titled “Semiconductor Device and Manufacturing Method Thereof,” filed on Apr. 4, 2022, the disclosure of which is incorporated by reference herein in its entirety.

### BACKGROUND

Image sensors are used to sense incoming visible or non-visible radiation, such as visible light and infrared light. Complementary metal-oxide-semiconductor (CMOS) image sensors (CIS) and charge-coupled device (CCD) sensors are used in various applications, such as digital still cameras, mobile phones, tablets, and goggles. These image sensors utilize an array of pixels that absorb (e.g., sense) the incoming radiation and convert it into electrical signals. An example of an image sensor is a backside illuminated (BSI) image sensor, which detects radiation from a “backside” of a substrate of the BSI image sensor.

### BRIEF DESCRIPTION OF THE DRAWINGS

Aspects of this disclosure are best understood from the following detailed description when read with the accompanying figures.

FIG. 1 illustrates a cross-sectional view of a BSI image sensor with isolation structures, in accordance with some embodiments.

FIG. 2 illustrates a cross-sectional view of a BSI image sensor with isolation structures and grid structures, in accordance with some embodiments.

FIG. 3 is a flow diagram of a method for fabricating a BSI image sensor with isolation structures, in accordance with some embodiments.

FIGS. 4-18 illustrate cross-sectional views of a BSI image sensor with isolation structures at various stages of its fabrication process, in accordance with some embodiments.

FIG. 19 is a flow diagram of a method for fabricating a BSI image sensor with isolation structures and grid structures, in accordance with some embodiments.

FIGS. 20-24 illustrate cross-sectional views of a BSI image sensor with isolation structures and grid structures at various stages of its fabrication process, in accordance with some embodiments.

Illustrative embodiments will now be described with reference to the accompanying drawings. In the drawings, like reference numerals generally indicate identical, functionally similar, and/or structurally similar elements. The discussion of elements with the same annotations applies to each other, unless mentioned otherwise.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

A BSI image sensor includes an array of pixel structures (which can include photodiodes, transistors, and other components) in a substrate (e.g., a semiconductor substrate). The pixel structures are configured to receive (or absorb) an electromagnetic radiation (e.g., infra-red radiation) projected toward the substrate and convert photons from the received radiation to electrical signals. The electrical signals are subsequently distributed to processing components attached to the BSI image sensor. The pixel structures overlie an interconnect structure configured to distribute the electrical signals generated within the pixel structures to appropriate processing components.

In the BSI image sensor, the interconnect structure is coupled to a front-side surface of the substrate, and color filters and micro-lenses are coupled to a back-side surface of the substrate to collect light with minimal or no obstructions from the elements of the interconnect structure and/or the pixel structures. As a result, BSI image sensors have improved performance under low light conditions and higher quantum efficiency (QE) (e.g., photon to electron conversion percentage) than front-side illuminated image sensors.

A challenge with BSI image sensors is reducing or eliminating cross-talk between adjacent pixel structures. The pixel structures that are adjacent to each other may interfere with each other's operation. This cross-talk may occur when light from one pixel structure makes its way into an adjacent pixel structure, thereby causing the adjacent pixel structure to sense the light. Such cross-talk can reduce the precision and the quantum efficiency of the BSI image sensor.

The present disclosure provides example BSI image sensors with isolation structures between adjacent pixel structures and example methods of forming the BSI image sensors. In some embodiments, the BSI image sensor can include a stack of isolation structures disposed between adjacent pixel structures to optically isolate the adjacent pixel structures from each other. In some embodiments, the stack of isolation structures can include a shallow trench isolation (STI) structure disposed on the front-side surface of the substrate of the BSI image sensor and a deep trench isolation (DTI) structure disposed on and in physical contact with the STI structure.

In some embodiments, the DTI structure can extend about 80 nm to about 130 nm above the back-side surface of the substrate of the BSI image sensor. In some embodiments, the STI structure can include one or more dielectric layers and the DTI structure can include a metal fill layer and a dielectric liner surrounding the metal fill layer. By including such metal fill layer in the DTI structure and extending the DTI structure above the back-side surface of the substrate, the cross-talk between adjacent pixel structures can be substantially minimized or eliminated, improving the quantum efficiency of the BSI image sensor.

In some embodiments, the quantum efficiency of the BSI image sensor can be further improved by including grooved regions on the back-side surface of the substrate that are substantially aligned to the pixel structures. In some embodiments, with the use of the grooved regions along with the DTI structures, the quantum efficiency of the BSI image sensor for detecting light in the near infra-red region (e.g., between a wavelength of about 800 nm and a wavelength of about 1000 nm) can be improved by about 0.5 times to about 1.5 times compared to BSI image sensors without the grooved regions and/or the DTI structures.

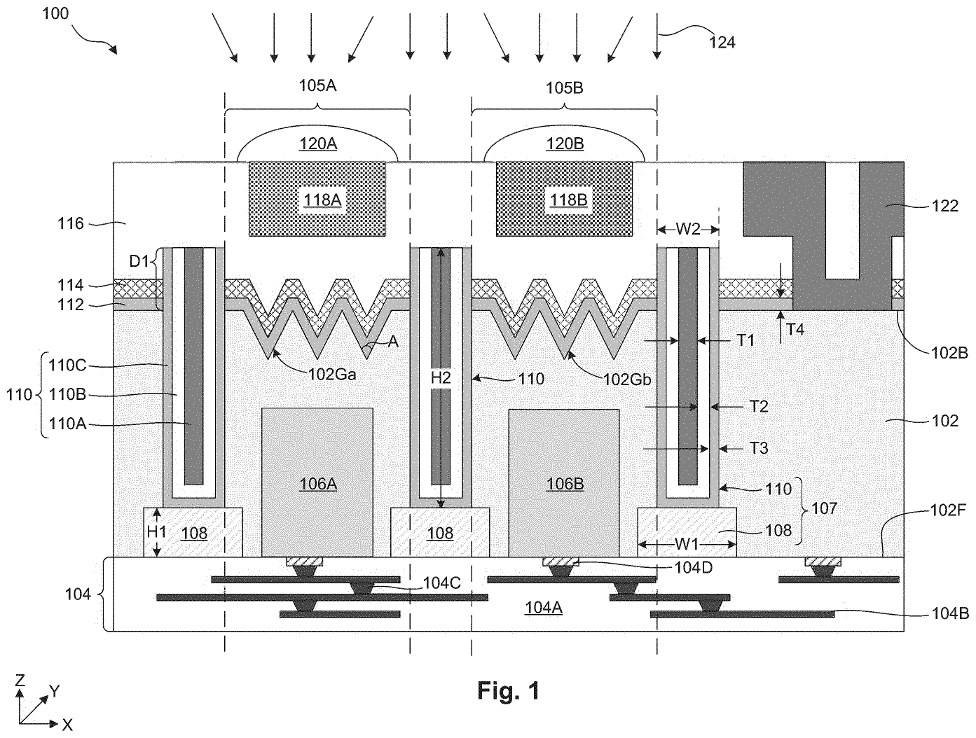

FIG. 1 illustrates a cross-sectional view of a BSI image sensor 100 (also referred to as an “optical device 100”), according to some embodiments. In some embodiments, BSI image sensor can include (i) a substrate 102 having a back-side surface 102B and a front-side surface 102F, (ii) an interconnect structure 104 disposed on front-side surface 102A of substrate 102, (iii) pixel structures 106A and 106B disposed in substrate 102, (iv) STI structures 108 disposed in substrate 102, (v) DTI structures 110 disposed on STI structures 108, (vi) an anti-reflective coating (ARC) 112 disposed on back-side surface 102B, (vii) a passivation layer 114 disposed on ARC 112, (viii) a dielectric layer 116 disposed on passivation layer 114, (ix) color filters 118A and 118B disposed in dielectric layer 116, (x) micro-lenses 120A and 120B disposed on dielectric layer 116, and (xi) a metal shielding layer 122.

In some embodiments, substrate 102 can be a semiconductor material, such as silicon, germanium (Ge), silicon germanium (SiGe), a silicon-on-insulator (SOI) structure, and a combination thereof. Further, substrate 102 can be doped with p-type dopants (e.g., boron, indium, aluminum, or gallium) or n-type dopants (e.g., phosphorus or arsenic).

In some embodiments, back-side surface 102B can include a first array of periodic grooved regions 102Ga and a second array of periodic grooved regions 102Gb. The first array of periodic grooved regions 102Ga can be substantially aligned to pixel structure 106A and the second array of periodic grooved regions 102Gb can be substantially aligned to pixel structure 106B. These arrays of periodic grooved regions 102Ga and 102Gb can provide a larger incident surface area for radiation beams 124 incident on each of pixel structures 106A and 106B compared to BSI image sensors with planar back-side surfaces and without periodic grooved regions in the back-side surfaces of the substrates. The larger incident surface area can improve the quantum efficiency of pixel structures 106A and 106B of the BSI image sensor 100.

In some embodiments, grooved regions 102Ga and 102Gb can have a triangular-shaped cross-sectional profile, as shown in FIG. 1. In some embodiments, grooved regions 102Ga and 102Gb can have other cross-sectional profiles, such as rectangular-shaped profiles and semi-oval shaped profiles. In some embodiments, grooved regions 102Ga and 102Gb can enable multiple reflections of incident radiation beams 124 at the inner sidewalls of grooved regions 102Ga and 102Gb without leaving grooved regions 102Ga and 102Gb. Such multiple reflections of incident radiation beams 124 can increase the likelihood and the amount of incident radiation beams 124 absorbed and processed by pixel structures 106A and 106B, thus improving the quantum efficiency of BSI image sensor 100. In some embodiments, each grooved region of the first and second arrays of grooved regions 102Ga-102Gb can have an angle A of about 60° to about 90° between inner sidewalls of the grooved regions to enable multiple reflections of incident radiation beams 124 at the inner sidewalls of grooved regions 102Ga and 102Gb.

In some embodiments, interconnect structure 104 can include an inter-metal dielectric (IMD) layer 104A, and metal lines 104B, metal vias 104C, and sensing devices 104D disposed in IMD layer 104A. Metal lines 104B and metal vias 104C form interconnects (e.g., wiring) between pixel structures 106A and 106B and other components (not shown in FIG. 1). In some embodiments, metal lines 104B and metal vias 104C can include an electrically conductive material, such as copper (Cu), ruthenium (Ru), cobalt (Co), a Cu alloy (e.g., Cu—Ru, Cu—Al, or copper-manganese (CuMn)), and any other suitable conductive material. The layout of metal lines 104B and metal vias 104C is exemplary and not limiting and other layout variations of metal lines 104B and metal vias 104C are within the scope of this disclosure. The number and arrangement of metal lines 104B and metal vias 104C can be different from the ones shown in FIG. 1.

In some embodiments, sensing devices 104D can be an array of field effect transistors (FETs) and/or memory cells that are electrically connected to respective pixel structures 106A and 106B and configured to read an electrical signal produced in those areas as a result of a light-to-charge conversion process. In some embodiments, interconnect structure 104 can be attached via a buffer layer (not shown in FIG. 1) to a carrier substrate (not shown in FIG. 1) that can provide support to the structures fabricated thereon (e.g., interconnect layer 104, substrate 102, etc.). The carrier substrate can be a silicon wafer, a glass substrate, or any other suitable material.

In some embodiments, pixel structures 106A and 106B (also referred to as “radiation-sensing regions 106A and 106B” or “radiation sensing devices 106A and 106B”) can be disposed in substrate 102. For example purposes, two pixel structures 106A and 106B are shown in FIG. 1, but additional pixel structures 106A and 106B can be implemented in substrate 102. Pixel structures 106A and 106B sense radiation, such as radiation beams 124 entering pixel regions 105A and 105B, respectively, and impinging back-side surface 102B at different incident angles. In some embodiments, each of pixel structures 106A and 106B can include a photodiode that can convert photons of radiation beams 124 to electrical charge. In some embodiments, pixel structures 106A and 106B can include photodiodes, transistors, amplifiers, other similar devices, or combinations thereof.

In some embodiments, pixel structures 106A and 106B can be electrically and optically isolated from each other with a stack of isolation structures 107. In some embodiments, each stack of isolation structures 107 can include STI structure 108 and DTI structure 110. STI structures 108 can be disposed in substrate 102 and surfaces of STI 108 facing interconnect structure 104 can be substantially coplanar with front-side surface 102F. In some embodiments, STI structures 108 can include a dielectric material, such as silicon oxide, silicon nitride, silicon oxynitride, fluorine-doped silicate glass (FSG), a low-k dielectric material (e.g., a material with a k value lower than 3.9), and any other suitable dielectric material.

In some embodiments, DTI structures 110 can be disposed on and in physical contact with STI structures 108. DTI structures 110 can be formed on STI structures 108 without any substantial gaps at the interfaces between DTI structures 110 and STI structures 108 to substantially minimize or prevent any optical leakage between pixel regions 105A and 105B and/or between pixel structures 106A and 106B, thus improving the quantum efficiency of pixel structures 106A and 106B. If gaps are present at the interfaces between DTI structures 110 and STI structures 108, radiation beams 124 (e.g., photons) entering pixel region 105A can travel to pixel region 105B through the gaps, and vice versa.

In some embodiments, DTI structures 110 can extend a distance Dl along a Z-axis above back-side surface 102B. Such extensions of DTI structures 110 over substrate 102 can substantially minimize or prevent radiation beams 124 (e.g., photons) entering pixel region 105A at incident angles greater than zero degrees from straying to pixel region 105B, and vice versa. As a result, a larger amount of photons can be captured and processed by pixel structures 106A and 106B by extending DTI structures 110 over substrate 102, thus, improving the quantum efficiency of BSI image sensor 100. In some embodiments, distance D1 can range from about 80 nm to about 130 nm. Within this range of distance D1, DTI structures 110 can improve the quantum efficiency of BSI image sensor 100 without compromising the size and manufacturing cost of BSI image sensor 100.

In some embodiments, each DTI structure 110 can include a metal fill layer 110A, a dielectric layer 110B surrounding metal fill layer 110, and a high-k dielectric layer 110C surrounding dielectric layer 110B. Dielectric layer 110B and high-k dielectric layer 110C can electrically isolate metal fill layer 110A from substrate 102 and/or pixel structures 106A and 106B. Metal fill layer 110A can block photons in pixel region 105A from straying to pixel region 105B through dielectric materials, and vice versa. Furthermore, metal fill layer 110A can enable multiple reflections of radiation beams 124 (e.g., photons) in pixel regions 105A and 105B without leaving pixel regions 105A and 105B. Such multiple reflections of radiation beams 124 can increase the amount of radiation beams 124 absorbed and processed by pixel structures 106A and 106B, thus improving the quantum efficiency of BSI image sensor 100. In some embodiments, with the use of metal fill layer 110A, DTI structures 110A can be formed with a width along an X-axis smaller than a width of DTI structures formed with dielectric layers and without metal fill layers because radiation beams can be more effectively blocked by a metal layer than a dielectric layer of substantially equal thickness. As a result, a smaller and more compact BSI image sensor 100 can be formed with DTI structures 110 without compromising its quantum efficiency.

In some embodiments, metal fill layer 110A can include a metallic material, such as tungsten (W), aluminum (Al), cobalt (Co), ruthenium (Ru), and other suitable metallic material. In some embodiments, dielectric layer 110B can include silicon oxide, silicon nitride, silicon oxynitride, or other suitable insulating oxide and/or nitride material. In some embodiments, high-k dielectric layer 110C can include a high-k material, such as hafnium oxide (HfO₂), aluminum oxide (Al₂O₃), any other suitable high-k dielectric material, and a combination thereof.

In some embodiments, STI structures 108 can have a height H1 of about 150 nm to about 250 nm along a Z-axis and a width W1 of about 300 nm to about 500 nm along an X-axis. In some embodiments, DTI structures 110 can have a height H2 of about 5 μm to about 10 μm along a Z-axis and a width W2 of about 300 nm to about 400 nm along an X-axis. In some embodiments, height H2 can be greater than height H1 for adequately preventing cross-talk between pixel structures 106A and 106B. In some embodiments, width W1 of STI structures 108 can be greater than width W2 of DTI structures 110 to adequately block photons from straying to adjacent pixel structures because unlike DTI structures 110, STI structures 108 may not have metal layers. As discussed above, photons can be more effectively blocked by a metal layer than a dielectric layer of substantially equal thickness. In some embodiments, metal fill layer 110A can have a thickness T1 of about 70 nm to about 150 nm along an X-axis, dielectric layer 110B can have a thickness T2 of about 100 nm to about 150 nm along an X-axis, and high-k dielectric layer 110C can have a thickness T3 of about 10 nm to about 20 nm along an X-axis. Within the above-mentioned ranges of thicknesses T2 and T3, dielectric layer 110B and high-k dielectric layer 110C can adequately electrically isolate metal fill layer 110A from substrate 102 and/or pixel structures 106A and 106B without compromising the size and manufacturing cost of BSI image sensor 100. Within the above-mentioned ranges of heights H1 and H2, widths W1 and W2 and thickness T1, STI structures 108 and DTI structures 110 can substantially minimize or prevent cross-talk between pixel structures 106A and 106B without compromising the size and manufacturing cost of BSI image sensor 100.

ARC 112 can be disposed on back-side surface 102B to prevent incident radiation beams 124 from being reflected away from pixel structures 106A and 106B. In some embodiments, ARC 112 can include a high-k dielectric material, such as hafnium oxide (HfO₂), tantalum pentoxide (Ta₂O₅), zirconium dioxide (ZrO₂), aluminum oxide (Al₂O₃), and any other suitable high-k dielectric material. In some embodiments, ARC 112 can have a thickness T4 of about 1 nm to about 50 nm. Within this range of thickness T4, ARC 112 can adequately prevent radiation beams 124 incident on pixel structures 106A and 106B from leaving pixel regions 105A and 105B without compromising the size and manufacturing cost of BSI image sensor 100. In some embodiments, ARC 112 and high-k dielectric layer 110C can include the same material. In some embodiments, passivation layer 114 can be disposed on ARC 112 and can include a dielectric material, such as silicon oxide (SiO₂), silicon nitride (Si₃N₄), silicon oxy-nitride (SiON), or any other suitable dielectric material. In some embodiments, dielectric layer 116 can include an oxide layer.

In some embodiments, color filters 118A and 118B can be disposed in dielectric layer 116 and top surfaces of color filters 118A and 118B can be substantially coplanar with top surface of dielectric layer 116. Color filters 118A and 118B can be substantially aligned with pixel structures 106A and 106B, respectively. In some embodiments, the color filters 118A and 118B can include a polymeric material. In some embodiments, micro-lenses 120A and 120B can be disposed on color filters 118A and 118B, respectively.

In some embodiments, metal shielding layer 122 (also referred to as a “black level correction layer 122”) can be disposed on back-side surface 102B and in dielectric layer 116, passivation layer 114, and ARC 112. Metal shielding layer 122 shields a black reference sensor (not shown) of BSI image sensor 100 from radiation beams 124. The black reference sensor can be used for generating reference black level signals in BSI image sensor 100. As a result of the shielding, the black reference sensor can provide a black reference signal for the image processing in BSI image sensor 100.

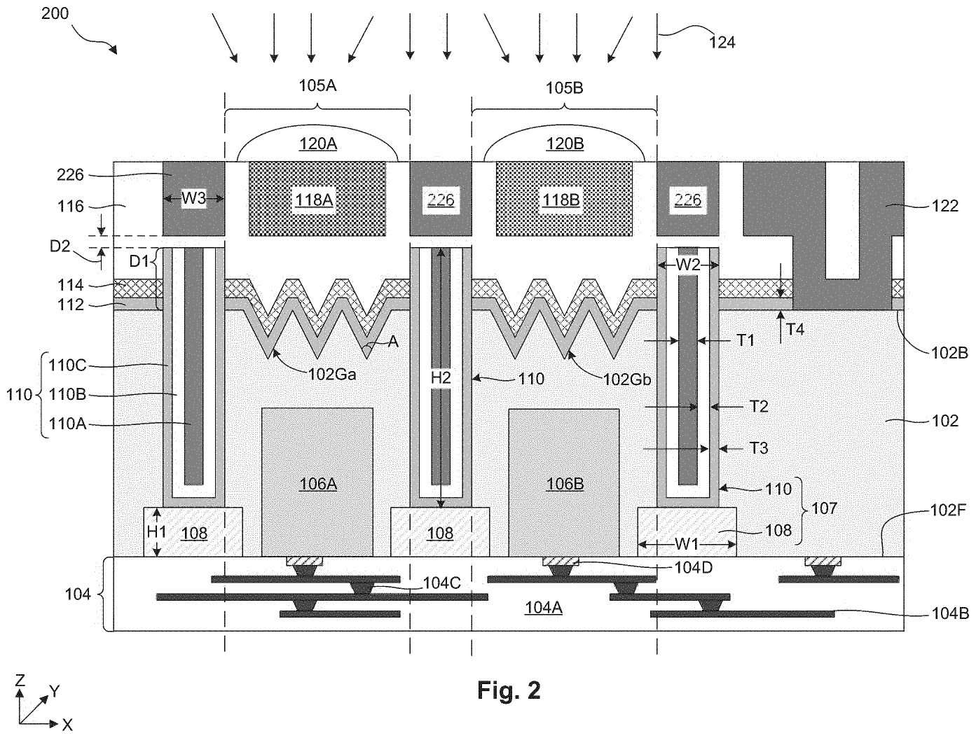

FIG. 2 illustrates a cross-sectional view of a BSI image sensor 200 (also referred to as an “optical device 200”), according to some embodiments. The discussion of BSI image sensor 100 applies to BSI image sensor 200, unless mentioned otherwise.

In some embodiments, BSI image sensor 200 can include metal grid structures 226 in addition to the elements of BSI image sensor 100. Metal grid structures 226 can be disposed in dielectric layer 116 and substantially aligned to DTI structures 110. In some embodiments, metal grid structures 226 can be separated from DTI structures 110 by a distance D2 of about 100 nm to about 300 nm along a Z-axis for the ease of fabrication. In some embodiments, grid structures can have width W3 of about 100 nm to about 300 nm along an X-axis. Within this range of width W3, metal grid structures 226 can substantially minimize or prevent cross-talk between pixel structures 106A and 106B without compromising the size and manufacturing cost of BSI image sensor 200. In some embodiments, width W3 can be greater or smaller than W2.

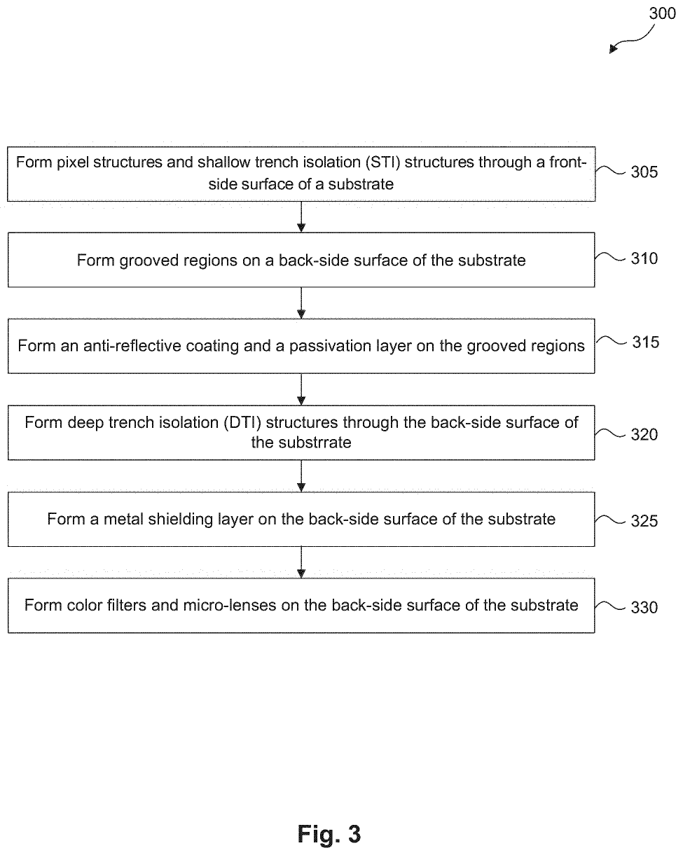

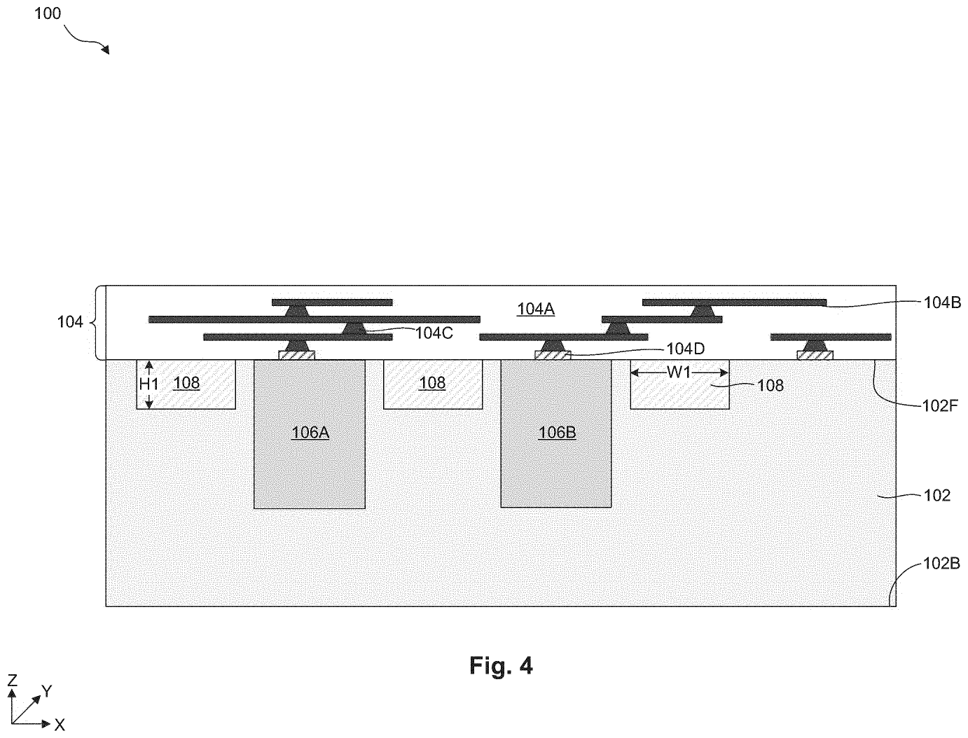

FIG. 3 is a flow diagram of an example method 300 for fabricating BSI image sensor 100 shown in FIG. 1, according to some embodiments. For illustrative purposes, the operations illustrated in FIG. 3 will be described with reference to the example fabrication process for fabricating BSI image sensor 100 as illustrated in FIGS. 4-18. FIGS. 4-18 are cross-sectional views of BSI image sensor 100 at various stages of fabrication, according to some embodiments. Operations can be performed in a different order or not performed depending on specific applications. It should be noted that method 300 may not produce a complete BSI image sensor 100. Accordingly, it is understood that additional processes can be provided before, during, and after method 300, and that some other processes may only be briefly described herein. Elements in FIGS. 4-18 with the same annotations as elements in FIG. 1 are described above.

Referring to FIG. 3, in operation 305, pixel structures and STI structures are formed through a front-side surface of a substrate. For example, as shown in FIG. 4, pixel structures 106A and 106B and STI structures 108 are formed through front-side surface 102F of substrate 102. In some embodiments, interconnect structure 104 can be formed on front-side surface 102F after the formation of STI structures 108.

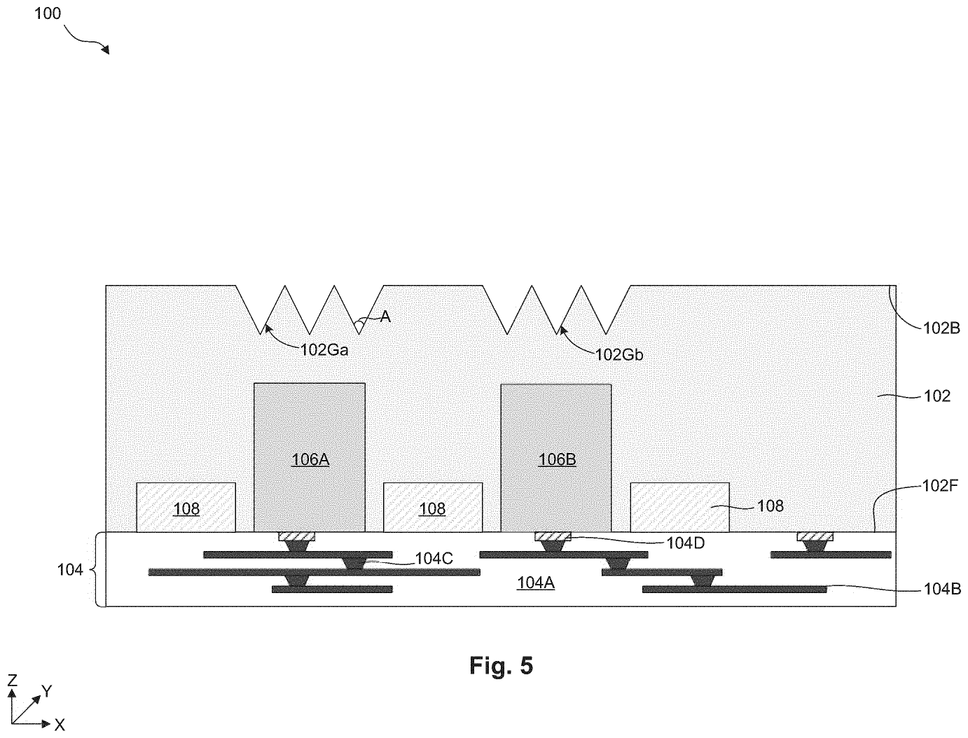

Referring to FIG. 3, in operation 310, grooved regions are formed on a back-side surface of the substrate. For example, as shown in FIG. 5, grooved regions 102Ga and 102Gb are formed on back-side surface 102B of substrate 102. In some embodiments, grooved regions 102Ga and 102Gb can be formed by performing a photolithographic process and an etching process on back-side surface 102B. In some embodiments, the triangular-shaped cross-sectional profile of grooved regions 102Ga and 102Gb can be formed by performing an anisotropic dry etching process followed by a wet etching process through a patterned masking layer (not shown) formed on back-side surface 102B.

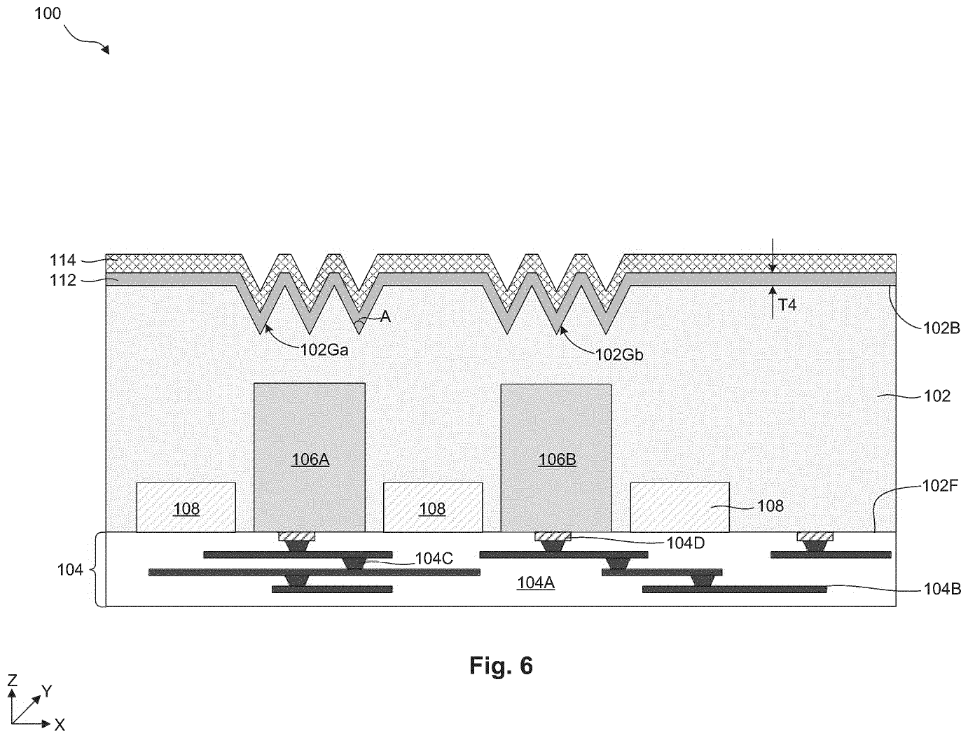

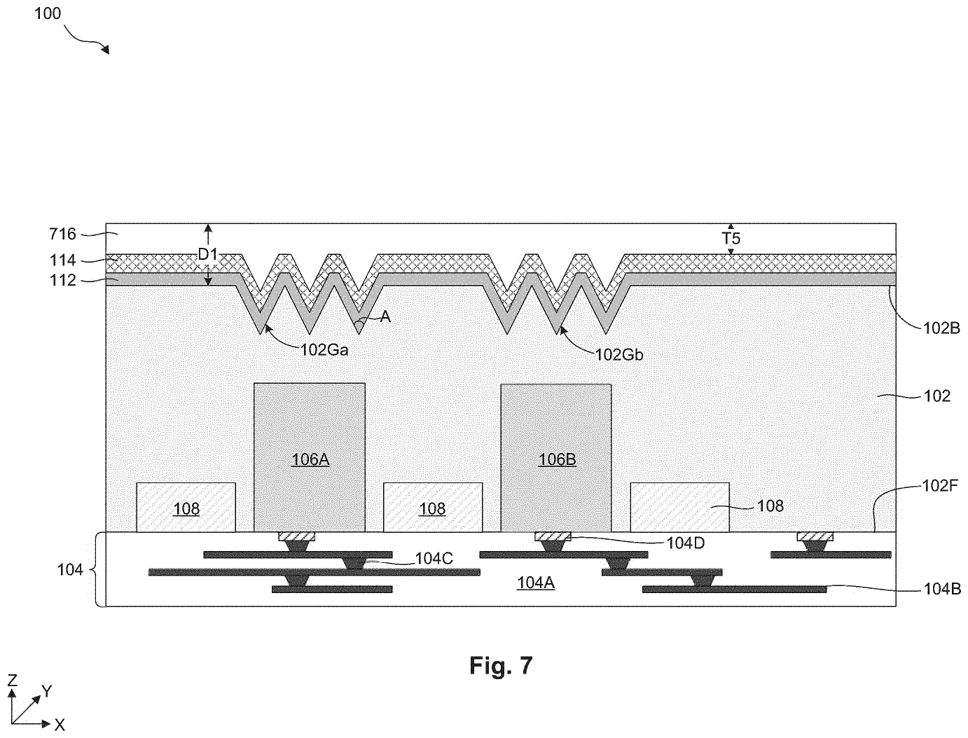

Referring to FIG. 3, in operation 315, an ARC and a passivation layer is formed on the grooved regions. For example as shown in FIG. 6, ARC 112 and passivation layer 114 are formed on grooved regions 102Ga and 102Gb. In some embodiments, the formation of ARC 112 can include depositing a high-k dielectric material on the structure of FIG. 5 using an atomic layer deposition (ALD) process, a chemical vapor deposition (CVD) process, or any other suitable high-k dielectric material deposition process. In some embodiments, the formation of passivation layer 114 can include depositing an oxide material on ARC 112 using an ALD process, a CVD process, or any other suitable oxide material deposition process. The formation of passivation layer 114 can be followed by a formation of a silicon oxide layer 716 on passivation layer 114, as shown in FIG. 7. The formation of silicon oxide layer 716 can include depositing silicon oxide layer 716 with a thickness T5 of about 100 nm to about 200 nm on the structure of FIG. 6 using a CVD process.

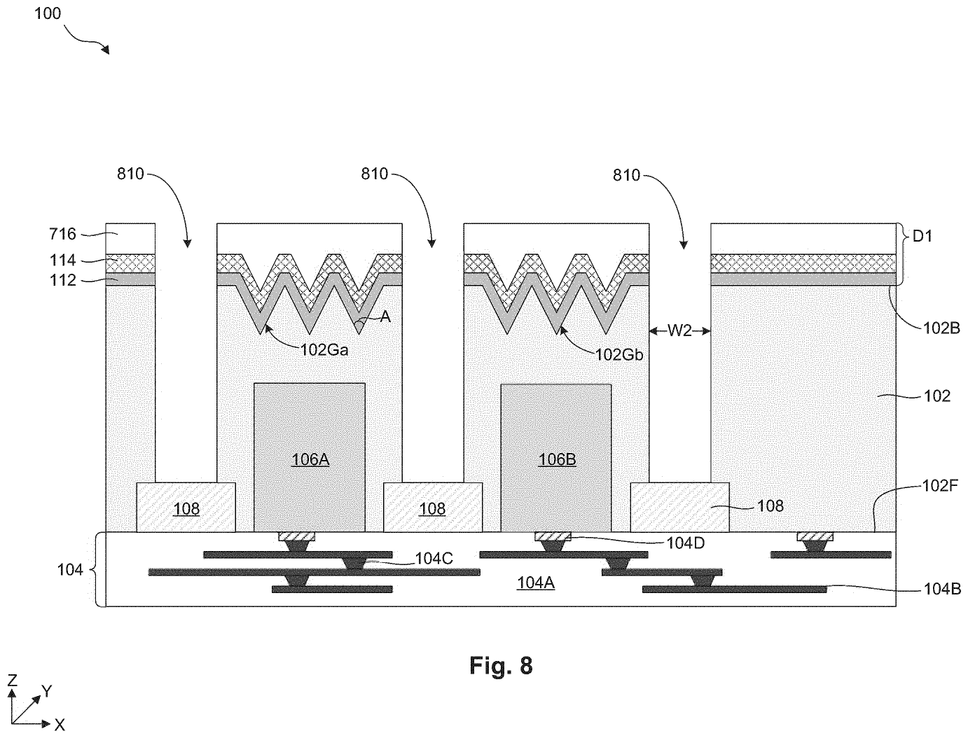

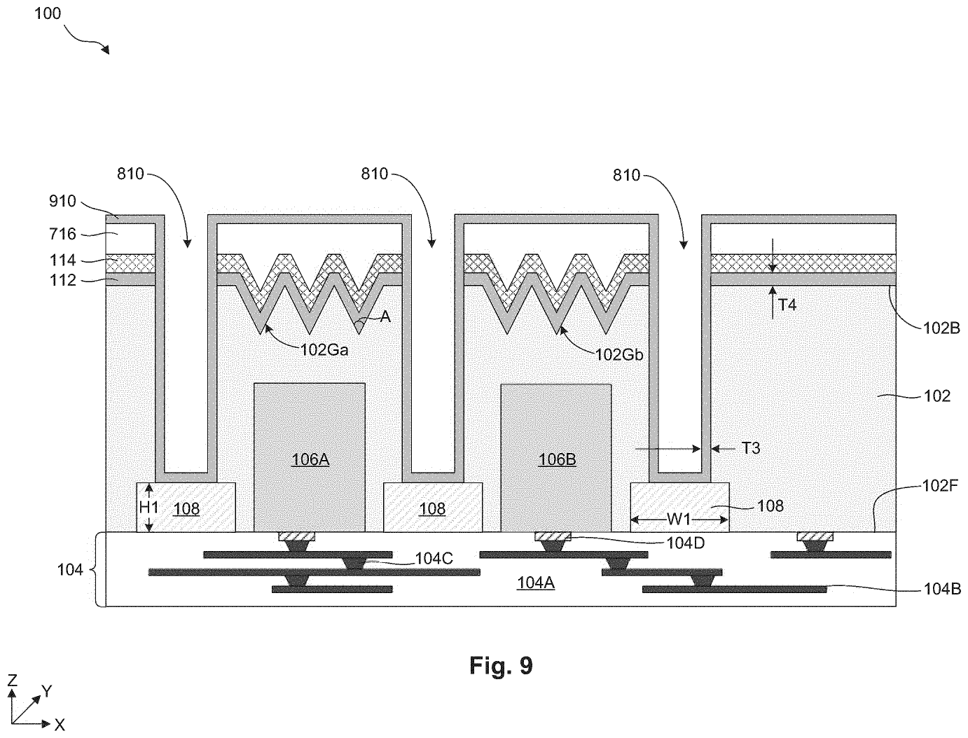

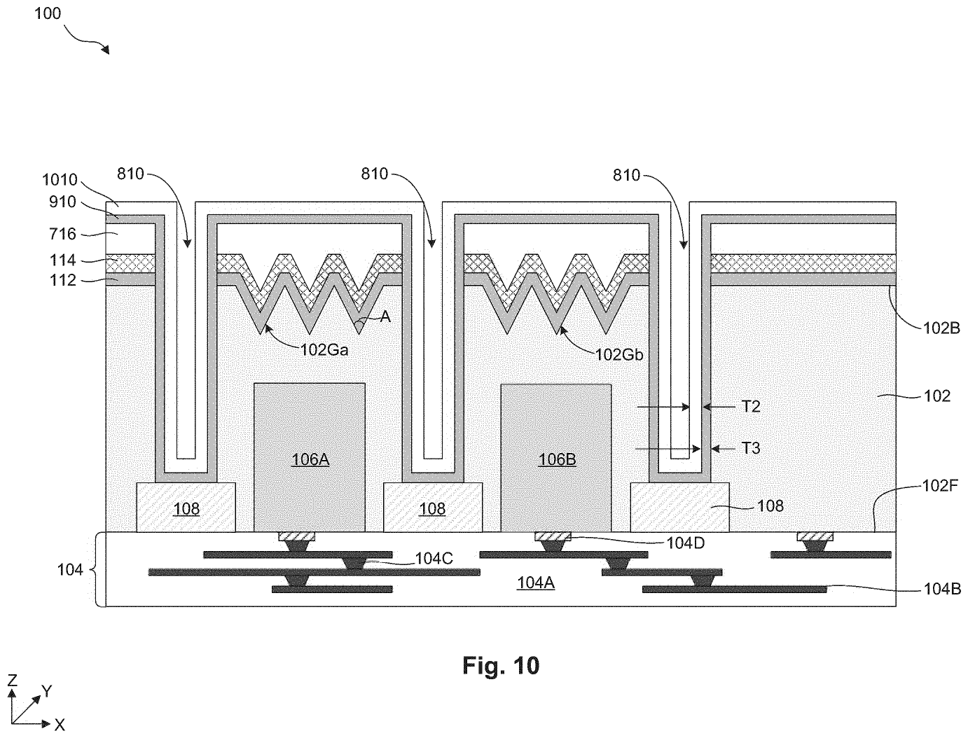

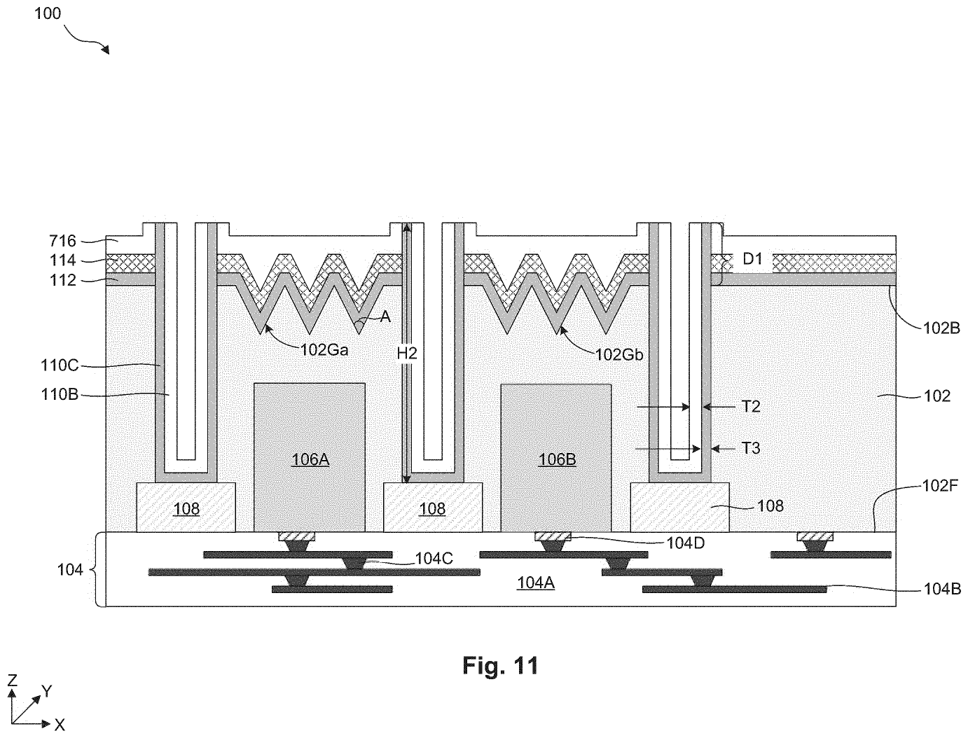

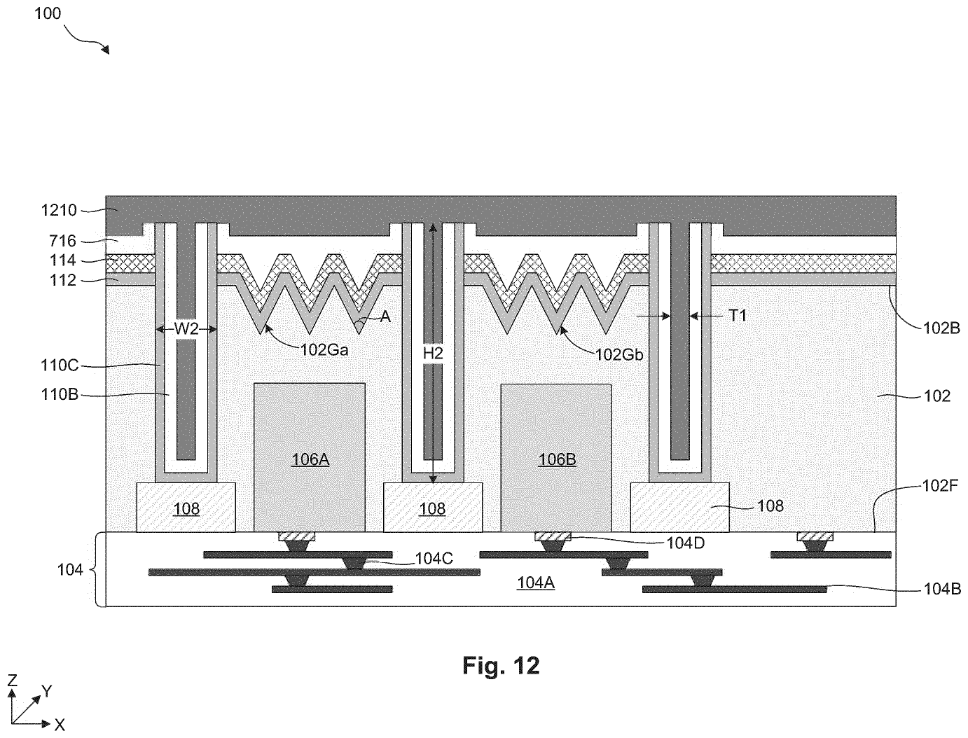

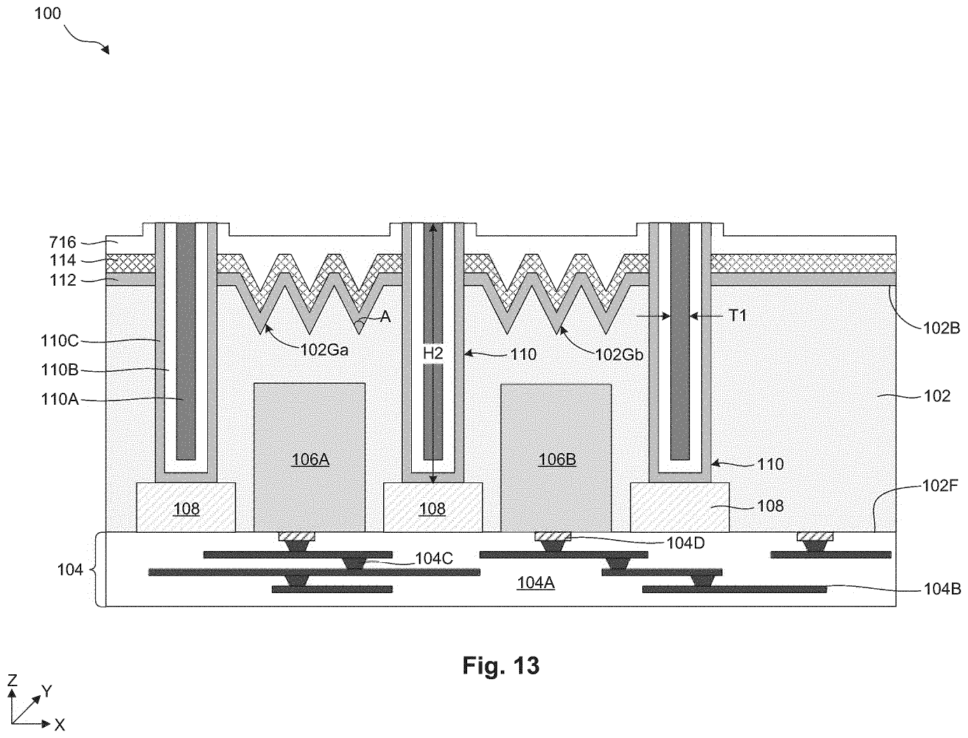

Referring to FIG. 3, in operation 320, DTI structures are formed through the back-side surface of the substrate. For example, as described with reference to FIGS. 8-13, DTI structures 110 are formed through back-side surface 102B. In some embodiments, the formation of DTI structures 110 can include sequential operations of (i) forming isolation trenches 810 with width W2 on STI structures 108, as shown in FIG. 8, (ii) forming a high-k dielectric layer 910 on the structure of FIG. 8 to form the structure of FIG. 9, (iii) forming an oxide layer 1010 on the structure of FIG. 9 to form the structure of FIG. 10, (iv) removing portions of high-k dielectric layer 910 and oxide layer 1010 outside isolation trenches 810 using an etching process to form the structure of FIG. 11, (v) depositing a metal layer 1210 on the structure of FIG. 11 to fill isolation trenches 810 and form the structure of FIG. 12, and (vi) removing portions of metal layer 1210 outside isolation trenches 810 using an etching process to form the structure of FIG. 13.

In some embodiments, the formation of isolation trenches 810 can include (i) forming a patterned photoresist layer (not shown) using a photolithographic process on the structure of FIG. 7, and (ii) performing an etching process on silicon oxide layer 716, passivation layer 114, ARC 112, and substrate 102 through the patterned photoresist layer to expose back-side surfaces of STI structures 108, as shown in FIG. 8.

In some embodiments, the formation of high-k dielectric layer 910 can include depositing a substantially conformal layer of HfO₂ and Al₂O₃ on top surfaces of silicon oxide layer 716, along sidewalls of isolation trenches 810, and exposed surfaces of STI structures 108 using an ALD process, as shown in FIG. 9. In some embodiments, the formation of oxide layer 1010 can include depositing a substantially conformal layer of silicon oxide on high-k dielectric layer 910 using an ALD process, as shown in FIG. 10.

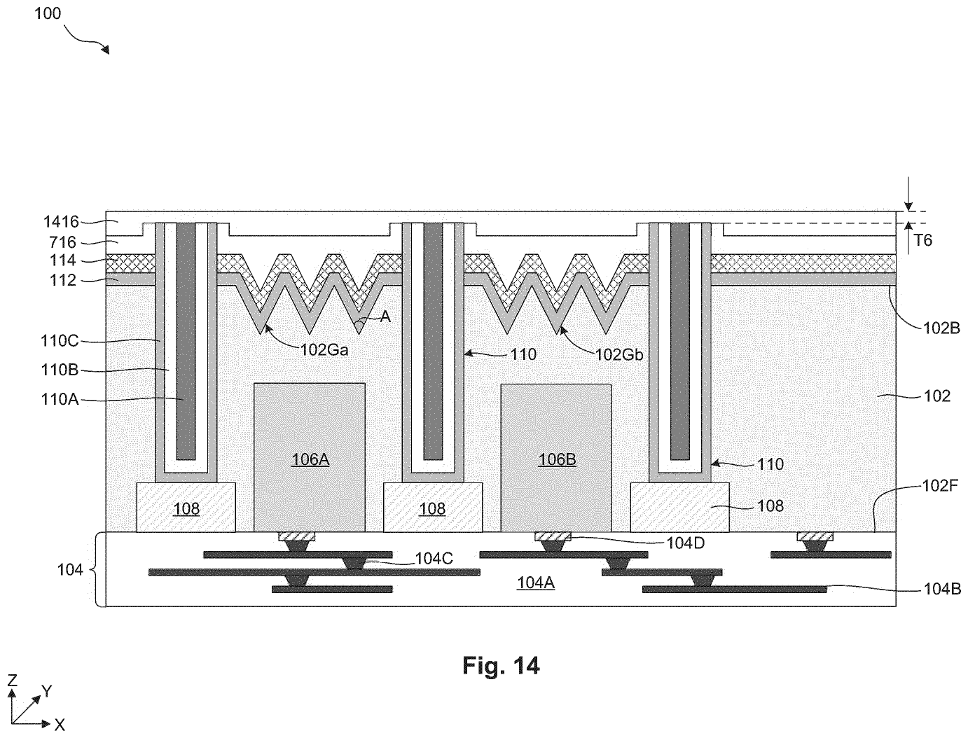

The formation of DTI structures 110 can be followed by a formation of a silicon oxide layer 1416 on the structure of FIG. 13 to form the structure of FIG. 14. The formation of silicon oxide layer 1416 can include depositing a silicon oxide layer (not shown) on the structure of FIG. 13 using a CVD process and performing a chemical mechanical polishing (CMP) process on the deposited silicon oxide layer to form silicon oxide layer 1416 with a thickness T6 of about 80 nm to about 130 nm on DTI structures 110. Silicon oxide layer 1416 can act as a buffer layer to protect DTI structures 110 from being etched during subsequent processing of BSI image sensor 100. Within the above-mentioned range of thickness T6, silicon oxide layer 1416 can adequately prevent the etching of DTI structures 110 during subsequent processing without compromising the size and manufacturing cost of BSI image sensor 100.

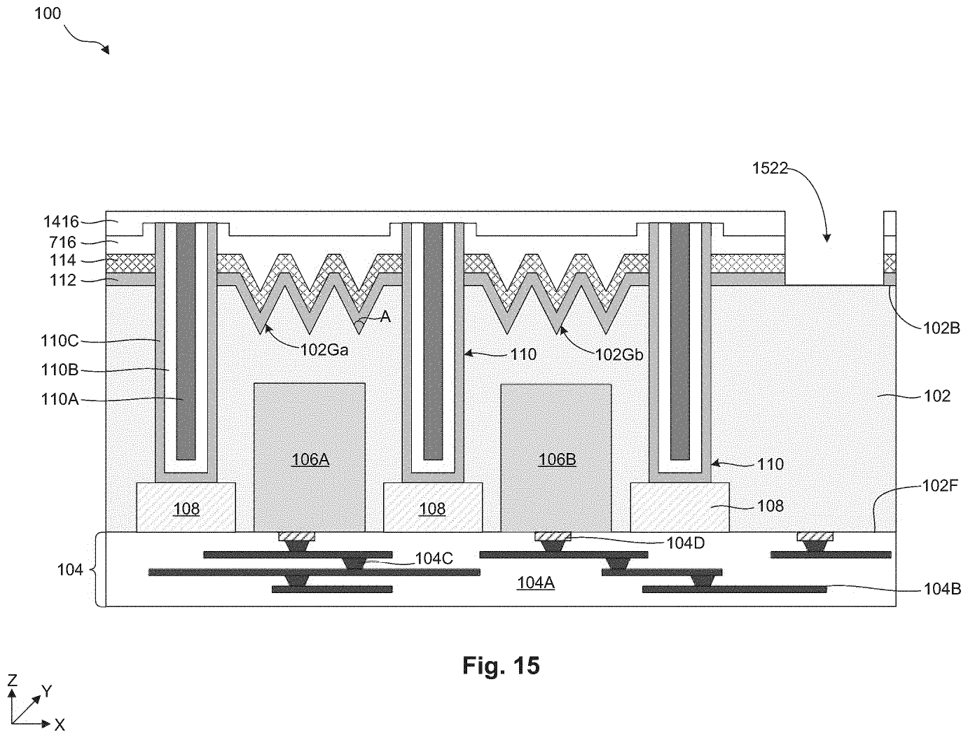

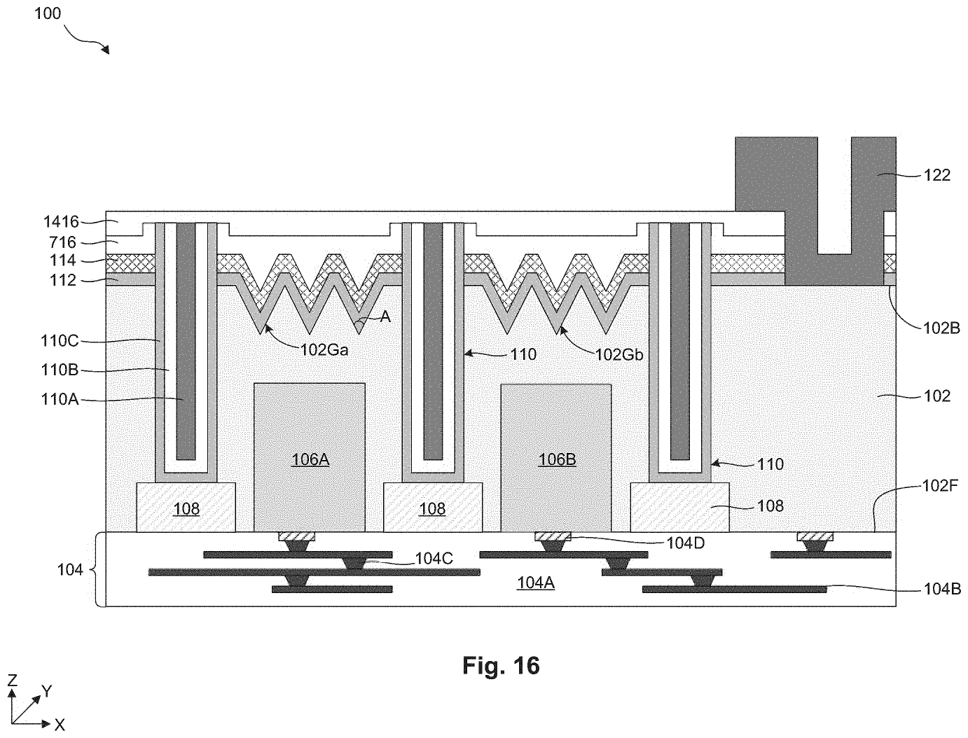

Referring to FIG. 3, in operation 325, a metal shielding layer is formed on the back-side surface of the substrate. For example, as described with reference to FIGS. 15 and 16, metal shielding layer 122 is formed on back-side surface 102B. In some embodiments, the formation of metal shielding layer 122 can include sequential operations of (i) forming a patterned photoresist layer (not shown) using a photolithographic process on the structure of FIG. 14, (ii) performing an etching process on silicon oxide layers 716 and 1416, passivation layer 114, and ARC 112, through the patterned photoresist layer to form opening 1522, as shown in FIG. 15, (iii) depositing a substantially conformal layer of metal (not shown) on top surfaces of silicon oxide layer 1416, along sidewalls of opening 1522, and exposed back-side surface 102B in opening 1522, (iv) forming a patterned masking layer (not shown) on the deposited substantially conformal layer of metal, and (v) etching the deposited substantially conformal layer of metal through the patterned masking layer to form the structure of FIG. 16.

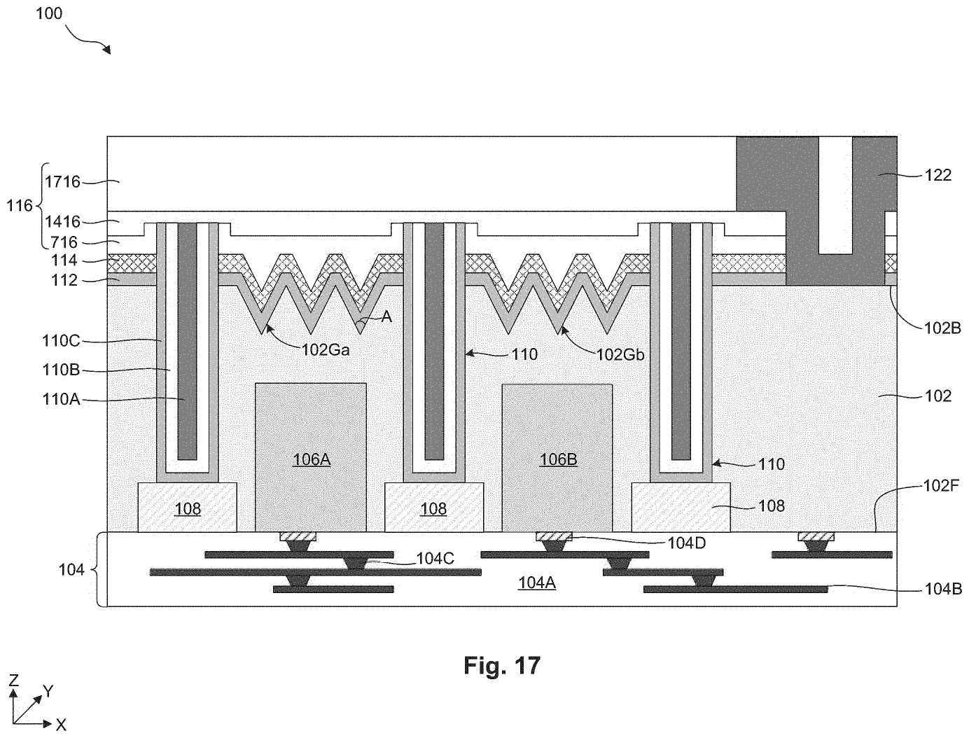

The formation of metal shielding layer 122 can be followed the formation of a silicon oxide layer 1716, as shown in FIG. 17. In some embodiments, the formation of silicon oxide layer 1716 can include depositing a layer of silicon oxide (not shown) on the structure of FIG. 16 and performing a CMP process on the deposited layer of silicon oxide to substantially coplanarize the top surface of silicon oxide layer 1716 with the top surface of metal shield layer 122, as shown in FIG. 17. Silicon oxide layers 716, 1416, and 1716 can form dielectric layer 116.

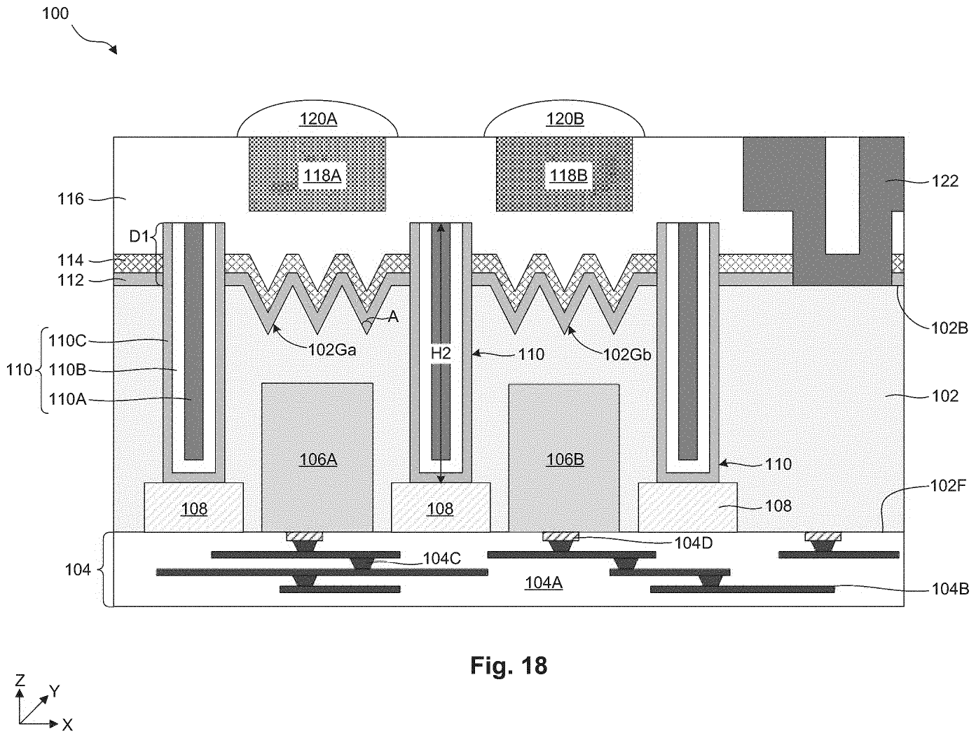

Referring to FIG. 3, in operation 330, color filters and micro-lenses are formed on the back-side surface of the substrate. For example, as shown in FIG. 18, color filters 118A and 118B can formed in dielectric layer 116 and micro-lenses 120A and 120B can be formed on color filters 118A and 118B, respectively.

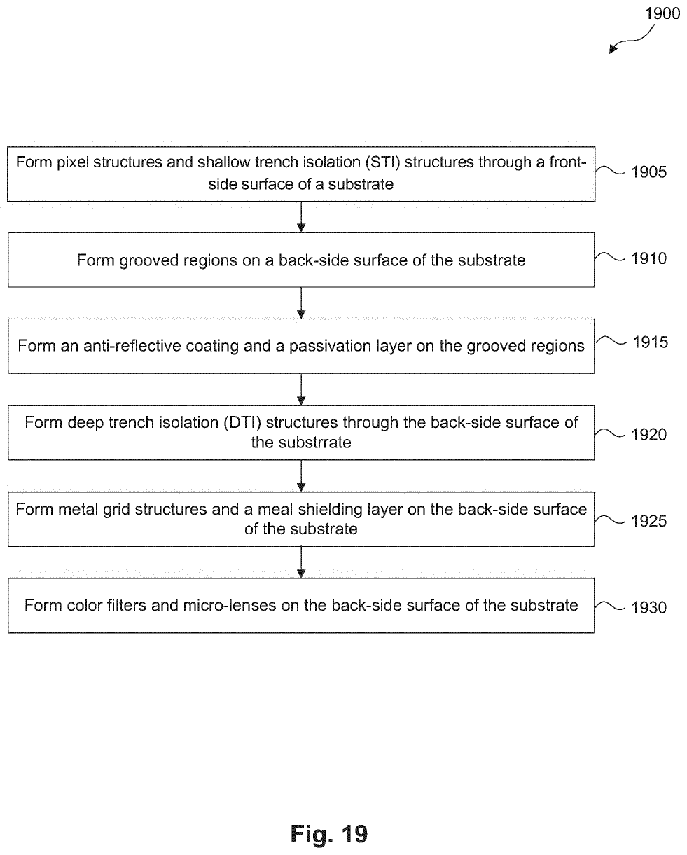

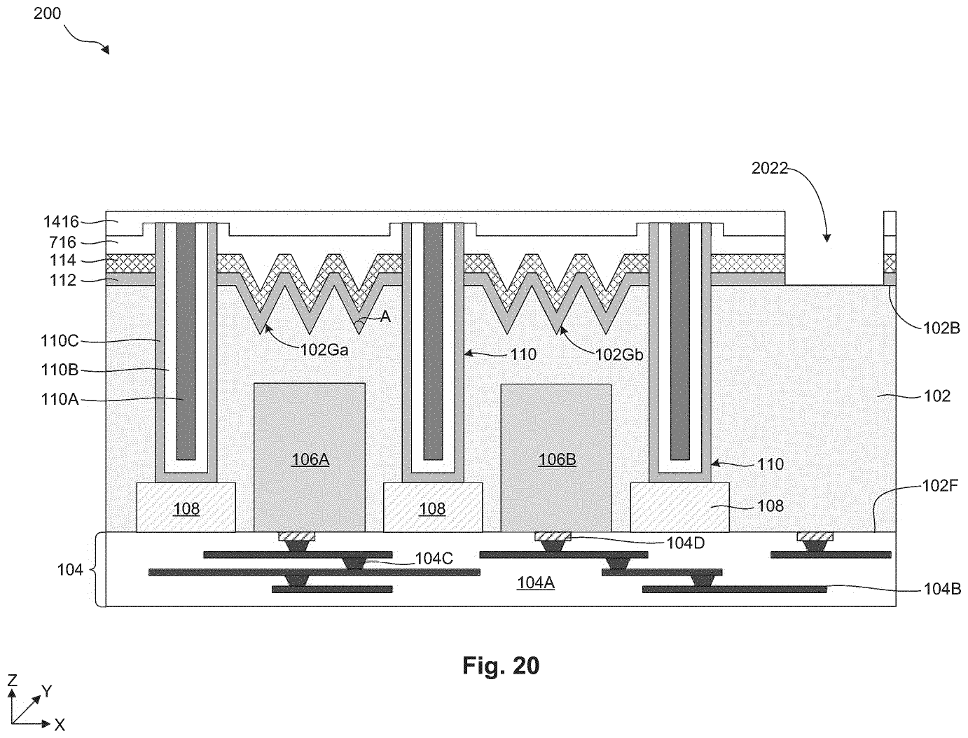

FIG. 19 is a flow diagram of an example method 1900 for fabricating BSI image sensor 200 shown in FIG. 2, according to some embodiments. For illustrative purposes, the operations illustrated in FIG. 19 will be described with reference to the example fabrication process for fabricating BSI image sensor 200 as illustrated in FIGS. 20-24. FIGS. 20-24 are cross-sectional views of BSI image sensor 200 at various stages of fabrication, according to some embodiments. Operations can be performed in a different order or not performed depending on specific applications. It should be noted that method 1900 may not produce a complete BSI image sensor 200. Accordingly, it is understood that additional processes can be provided before, during, and after method 1900, and that some other processes may only be briefly described herein. Elements in FIGS. 20-24 with the same annotations as elements in FIGS. 1-2 are described above.

Referring to FIG. 19, operations 1905-1920 are similar to operations 305-320 of FIG. 3. After operation 1920, structure similar to the structure of FIG. 14 is formed. The subsequent processing on the structure of FIG. 14 in operations 1925-1930 are described with reference to FIGS. 20-24.

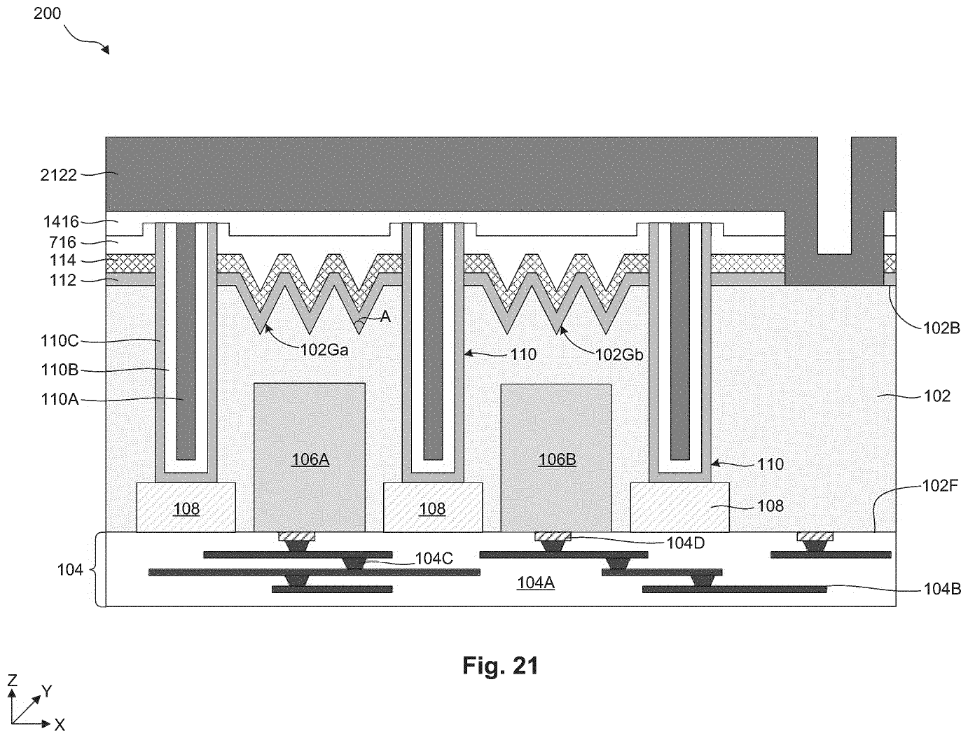

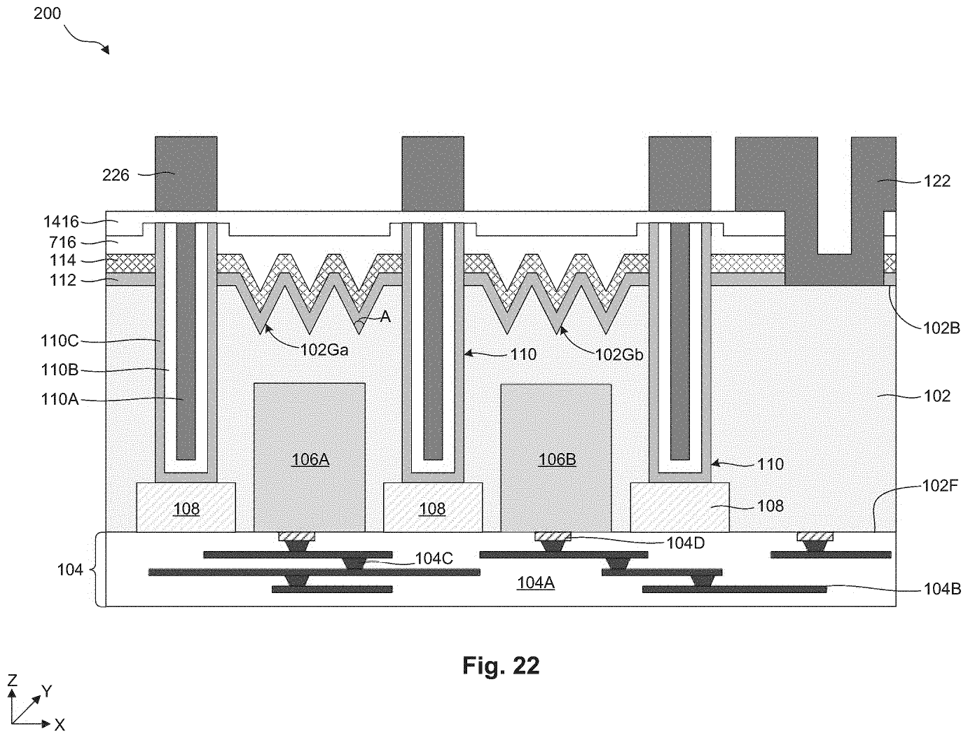

Referring to FIG. 19, in operation 1925, metal grid structures and a metal shielding layer are formed on the back-side surface of the substrate. For example, as described with reference to FIGS. 20-22, metal grid structures 226 and metal shielding layer 122 are formed on back-side surface 102B. In some embodiments, the formation of metal grid structures 226 and metal shielding layer 122 can include sequential operations of (i) forming a patterned photoresist layer (not shown) using a photolithographic process on a structure similar to the structure of FIG. 14, (ii) performing an etching process on silicon oxide layers 716 and 1416, passivation layer 114, and ARC 112, through the patterned photoresist layer to form opening 2022, as shown in FIG. 20, (iii) depositing a substantially conformal metal layer 2122 on top surfaces of silicon oxide layer 1416, along sidewalls of opening 2022, and exposed back-side surface 102B in opening 1522, as shown in FIG. 21, (iv) forming a patterned masking layer (not shown) on metal layer 2122, and (v) etching metal layer 2122 through the patterned masking layer to form the structure of FIG. 22. In some embodiments, metal grid structures 122 can be formed without forming metal shielding layer 122 in operation 1925. That is, metal shielding layer 122 may not be formed in operation 1925.

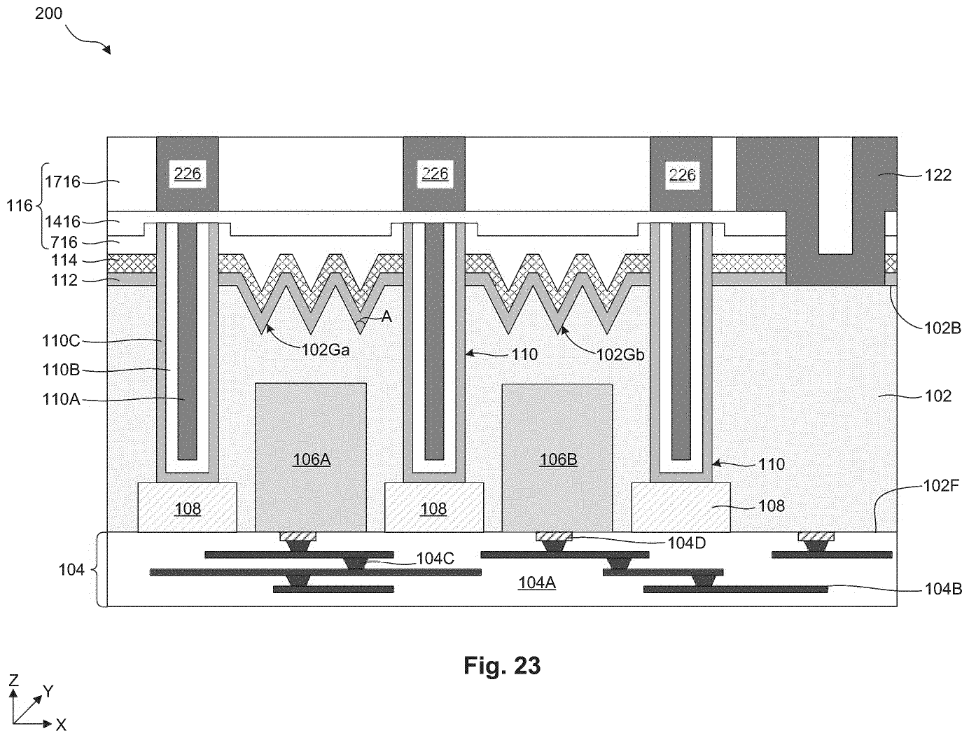

The formation of metal grid structures 226 and metal shielding layer 122 can be followed the formation of a silicon oxide layer 1716, as shown in FIG. 23. In some embodiments, the formation of silicon oxide layer 1716 can include depositing a layer of silicon oxide (not shown) on the structure of FIG. 22 and performing a CMP process on the deposited layer of silicon oxide to substantially coplanarize the top surface of silicon oxide layer 1716 with the top surfaces of metal grid structures 226 and metal shield layer 122, as shown in FIG. 23. Silicon oxide layers 716, 1416, and 1716 can form dielectric layer 116.

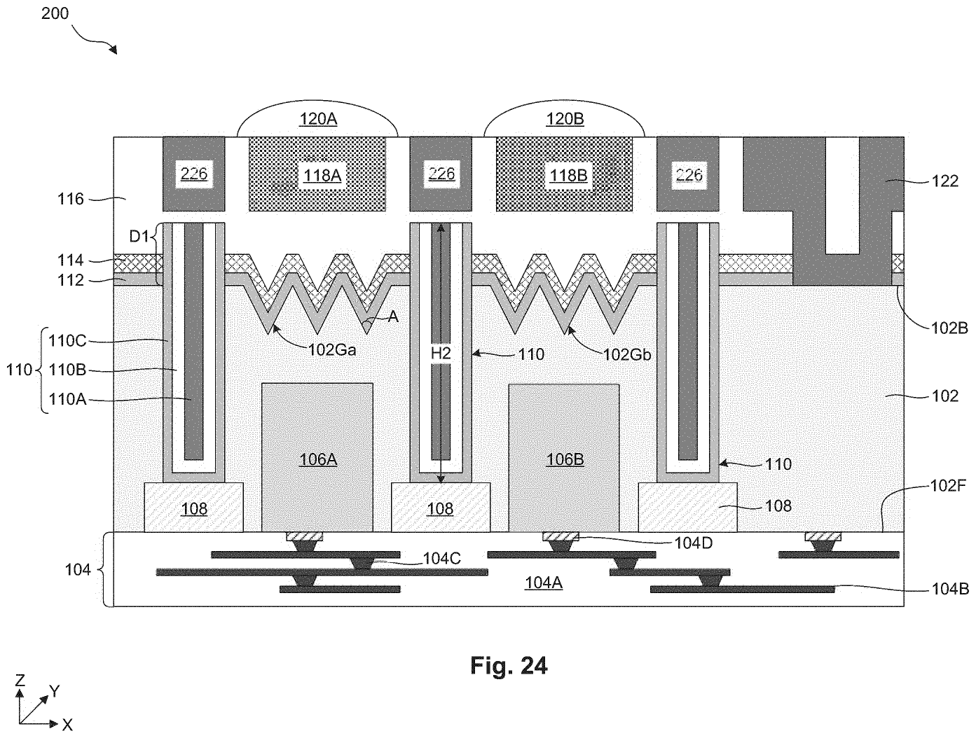

Referring to FIG. 19, in operation 1930, color filters and micro-lenses are formed on the back-side surface of the substrate. For example, as shown in FIG. 24, color filters 118A and 118B can formed in dielectric layer 116 and micro-lenses 120A and 120B can be formed on color filters 118A and 118B, respectively.

The present disclosure provides example BSI image sensors (e.g., BSI image sensors 100 and 200) with isolation structures (e.g., DTI structures 110 and STI structures 108) between adjacent pixel structures (e.g., pixel structures 106A and 106B) and example methods (e.g., methods 300 and 1900) of forming the BSI image sensors. In some embodiments, the BSI image sensor can include a stack of isolation structures disposed between adjacent pixel structures to optically isolate the adjacent pixel structures from each other. In some embodiments, the stack of isolation structures can include a shallow trench isolation (STI) structure disposed on the front-side surface (e.g., front-side surface 102F) of the substrate (e.g., substrate 102) of the BSI image sensor and a deep trench isolation (DTI) structure disposed on and in physical contact with the STI structure.

In some embodiments, the DTI structure can extend about 80 nm to about 130 nm above the back-side surface (e.g., back-side surface 102B) of the substrate of the BSI image sensor. In some embodiments, the STI structure can include one or more dielectric layers and the DTI structure can include a metal fill layer (e.g., metal fill layer 110A) and a dielectric liner (e.g., dielectric layers 110B and 110C) surrounding the metal fill layer. By including such metal fill layer in the DTI structure and extending the DTI structure above the back-side surface of the substrate, the cross-talk between adjacent pixel structures (e.g., pixel structures 106A and 106B) can be substantially minimized or eliminated, improving the quantum efficiency of the BSI image sensor.

In some embodiments, the quantum efficiency of the BSI image sensor can be further improved by including grooved regions (e.g., grooved regions 102Ga and 102Gb) on the back-side surface of the substrate that are substantially aligned to the pixel structures. In some embodiments, with the use of the grooved regions along with the DTI structures, the quantum efficiency of the BSI image sensor for detecting light in the near infra-red region (e.g., between a wavelength of about 800 nm and a wavelength of about 1000 nm) can be improved by about 0.5 times to about 1.5 times compared to BSI image sensors without the grooved regions and/or the DTI structures.

In some embodiments, an optical device includes a substrate having a first surface and a second surface opposite to the first surface, first and second radiation sensing devices disposed in the substrate, a first isolation structure disposed in the substrate and having a first surface and a second surface opposite to the first surface, and a second isolation structure disposed in the substrate and on the first surface of the first isolation structure. The second isolation structure includes a metal layer and a dielectric layer surrounding the metal layer. The second isolation structure vertically extends over the first surface of the substrate.

In some embodiments, an optical device includes a substrate having a front-side surface and a back-side surface, first and second pixel structures disposed in the substrate, an STI structure disposed between the first and second pixel structures, a DTI structure disposed on the STI structure, and a grid structure disposed on the back-side surface of the substrate and substantially aligned with the DTI structure. The DTI structure includes a metal layer and a dielectric liner disposed along sidewalls of the metal layer and on the STI structure.

In some embodiments, a method includes forming first and second radiation sensing devices through a first surface of a substrate, forming a first isolation structure through the first surface of the substrate and between the first and second radiation sensing devices, forming grooved regions on a second surface of the substrate that is opposite to the first surface of the substrate, forming an isolation trench through the second surface of the substrate and on the first isolation structure, forming a dielectric layer in the isolation trench, and forming a metal layer on the dielectric layer. The dielectric layer vertically extends over the second surface of the substrate.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An optical device, comprising:
a substrate comprising a first surface and a second surface opposite to the first surface;
first and second radiation sensing devices disposed in the substrate;
a first isolation structure disposed in the substrate and between the first and second radiation sensing devices, the first isolation structure comprising a first surface and a second surface opposite to the first surface; and
a second isolation structure disposed in the substrate and on the first surface of the first isolation structure, comprising:
a metal structure; and
a dielectric layer surrounding the metal structure;
wherein the second isolation structure vertically extends over the first surface of the substrate.

2. The optical device of claim 1, wherein the second surface of the first isolation structure is substantially coplanar with the second surface of the substrate.

3. The optical device of claim 1, wherein a height of the second isolation structure is greater than a height of the first isolation structure.

4. The optical device of claim 1, wherein a width of the first isolation structure is greater than a width of the second isolation structure.

5. The optical device of claim 1, wherein the second isolation structure vertically extends by a distance of about 80 nm to about 130 nm over the first surface of the substrate.

6. The optical device of claim 1, wherein the dielectric layer is in physical contact with the first surface of the first isolation structure.

7. The optical device of claim 1, wherein the dielectric layer comprises:
an oxide layer surrounding the metal structure; and
a high-k dielectric layer surrounding the oxide layer,
wherein materials of the oxide layer and the high-k dielectric layer are different from each other.

8. The optical device of claim 1, wherein the dielectric layer comprises:
a silicon oxide layer surrounding the metal structure; and
a high-k dielectric layer comprising hafnium oxide and aluminum oxide surrounding the silicon oxide layer.

9. The optical device of claim 1, wherein the metal structure comprises tungsten or aluminum.

10. The optical device of claim 1, wherein the first surface of the substrate comprises grooved regions substantially aligned with the first and second radiation sensing devices.

11. The optical device of claim 10, wherein the grooved regions comprises triangular-shaped profiles.

12. The optical device of claim 1, further comprising a buffer layer on the second isolation structure.

13. An optical device, comprising:
a substrate comprising a front-side surface and a back-side surface;
first and second pixel structures disposed in the substrate;
a shallow trench isolation (STI) structure disposed between the first and second pixel structures;
a deep trench isolation (DTI) structure disposed on the STI structure, comprising:
a metal structure; and
a dielectric liner disposed along sidewalls of the metal structure and on the STI structure; and
a grid structure disposed on the back-side surface of the substrate and substantially aligned with the DTI structure.

14. The optical device of claim 13, wherein the dielectric liner comprises:
a silicon oxide layer surrounding the metal structure; and
a high-k dielectric layer comprising hafnium oxide and aluminum oxide surrounding the silicon oxide layer.

15. The optical device of claim 13, wherein the metal structure comprises tungsten or aluminum.

16. The optical device of claim 13, further comprising a buffer layer between the metal structure and the grid structure.

17. A method, comprising:
forming first and second radiation sensing devices through a first surface of a substrate;
forming a first isolation structure through the first surface of the substrate and between the first and second radiation sensing devices;
forming grooved regions on a second surface of the substrate that is opposite to the first surface of the substrate;
forming an isolation trench through the second surface of the substrate and on the first isolation structure;
forming a dielectric layer in the isolation trench, wherein the dielectric layer vertically extends over the second surface of the substrate; and
forming a metal layer on the dielectric layer.

18. The method of claim 17, wherein forming the dielectric layer comprises:
depositing a high-k dielectric layer along sidewalls of the isolation trench and on the first isolation structure; and
depositing an oxide layer on the high-k dielectric layer, wherein materials of the oxide layer and the high-k dielectric layer are different from each other.

19. The method of claim 17, further comprising forming a grid structure on the metal layer.

20. The method of claim 19, further comprising forming a buffer layer between the metal layer and the grid structure.
